(19) United States
(12) Patent Application Publication
(10) Pub. No.: US 2025/0132209 A1
(43) Pub. Date: Apr. 24, 2025

(54) SEMICONDUCTOR DEVICES AND SEMICONDUCTOR DEVICE ASSEMBLIES WITH INK-JET PRINTED CONDUCTIVE PADS AND METHODS FOR MAKING THE SAME

(71) Applicant: Micron Technology, Inc., Boise, ID (US)

(72) Inventor: Kunal R. Parekh, Boise, ID (US)

(21) Appl. No.: 18/914,866

(22) Filed: Oct. 14, 2024

Related U.S. Application Data
(60) Provisional application No. 63/545,510, filed on Oct. 24, 2023.

(51) Int. Cl. H01L 21/66; B41M 5/00; B41M 7/00; H01L 25/065

(52) U.S. Cl. CPC H01L 22/32; B41M 5/0047; B41M 7/009; H01L 25/0657; H01L 2225/06541

(57) ABSTRACT

A method for forming a semiconductor device assembly is described. The method comprises vertically stacking at least one semiconductor device over a substrate; and ink-jet printing, after vertically stacking the at least one semiconductor device, a conductive pad on an exposed conductor of the at least one semiconductor device or of the substrate. The method can further include testing an electrical circuit of the semiconductor device assembly by electrically probing the electrical circuit through the conductive pad.

### CROSS-REFERENCE TO RELATED APPLICATION(S)

The present application claims priority to U.S. Provisional Patent Application No. 63/545,510, filed Oct. 24, 2023, the disclosure of which is incorporated herein by reference in its entirety.

### TECHNICAL FIELD

The present disclosure generally relates to semiconductor device assemblies, and more particularly relates to semiconductor devices and semiconductor device assemblies with ink-jet printed conductive pads and methods for making the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1 and 2 are simplified schematic cross-sectional views of an example semiconductor device assembly in accordance with various embodiments of the present technology.

FIG. 3 is a simplified schematic overhead view of an example semiconductor device assembly in accordance with various embodiments of the present technology.

FIG. 4 is a flow chart illustrating a method of forming a semiconductor device assembly in accordance with an embodiment of the present technology.

FIG. 5 is a schematic view showing a system that includes a semiconductor device assembly configured in accordance with an embodiment of the present technology.

### DETAILED DESCRIPTION

Semiconductor device assemblies frequently include a number of semiconductor devices stacked together, sometimes over a package-level substrate such as a printed circuit board (PCB), or sometimes over a larger semiconductor device (e.g., a logic device or interposer). The stacking operation involves forming a large number of electrical interconnects between the semiconductor devices, and can involve process steps that heat, cool, move, add material to, or remove material from the assembly. As a result of these operations, some of the electrical interconnects in the assembly may be compromised, as can active circuits in the devices. Although testing the functionality of devices can be easily accomplished before they are assembled, testing the functionality of the devices after stacking (to ensure that the process steps did not negatively affect the interconnects and/or circuitry in the assembly) can pose a challenge. Stacked device assemblies are not easily compatible with lithographic approaches for forming conductive probe pads thereon, and pre-positioning accessible probe pads for testing post-stacking may not always be feasible or compatible with subsequent assembly steps.

To address these drawbacks and others, various embodiments of the present application provide semiconductor device assemblies with conductive pads, suitable for probing to electrically test an assembly post-stacking, using ink-jet printing of conductive probe pads. The probe pads can be directly formed on an exposed conductive element of one of the devices or formed concurrently with ink-jet printed traces that route signals from the exposed conductor to the probe pad. The ink-jet printing process can be compatible with stacked devices due to the ability to position an ink-jet nozzle in different vertical planes (without the challenges posed by shifting out of the focal plane of a lithographic masking tool), and can provide probe pads on any convenient surface of the stacked assembly (e.g., an upper surface of the top device, or an exposed shelf of a lower device not covered by any upper device in the stack).

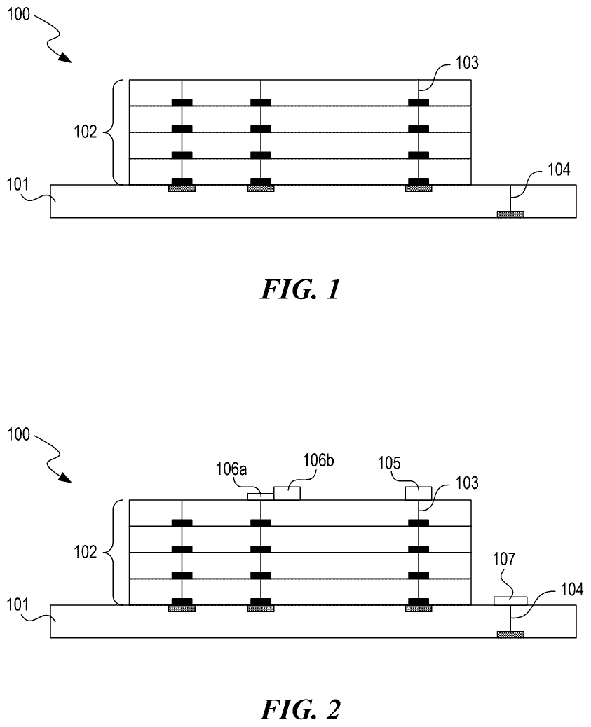

For example, FIG. 1 is a simplified schematic cross-sectional view of an example semiconductor device assembly 100, in which a vertical stack of dies 102 have been disposed over a substrate 101 (e.g., a larger die, an interposer, a printed circuit board, etc.). The active circuitry (not illustrated) of the assembly 100 may be at least partially interconnected by a plurality of through-silicon vias (TSVs) 103 (coupled to TSVs in adjacent dies by interconnects, unlabeled) that are disposed in the stack of dies 102, and/or may be coupled to a conductor 104 in the substrate 101. Following the stacking operation (e.g., pick-and-place, tacking, gang bonding, etc.) that couples the stack of dies 102 to the substrate 101, it may be desirable to functionally test the circuitry of the assembly 100 before subsequent assembly steps (e.g., encapsulation) that would either represent an unwarranted further investment of time and parts into a defective assembly, or which would prevent reclamation/repair.

Accordingly, conductive pads can be formed on the assembly by ink-jet printing a conductive material (e.g., comprising conductive nanoparticles suspended in a liquid medium that can be evaporated/driven off by heat, low pressure, or even a short delay in normal atmospheric conditions) in direct contact with an exposed conductor of the assembly. In this regard, the TSVs 103 of the uppermost die in the stack of dies 102 may be exposed, either before or after the stacking operation, by an etching or polishing step on the backside (the exposed upper surface) of the die. Alternatively and/or additionally, a pre-positioned conductor in the substrate 101 can be exposed in advance of stacking (albeit without a plated pad, which might cause the upper surface of the substrate 101 to be disadvantageously non-planar for the stacking operation) or exposed by an etching operation subsequent to stacking. Either or both of these conductive structures, or others similarly exposed, can be operably connected to functional circuitry in the assembly 100 that it would be desirable to test, and accordingly can have a conductive pad printed directly thereon, as illustrated in FIG. 2.

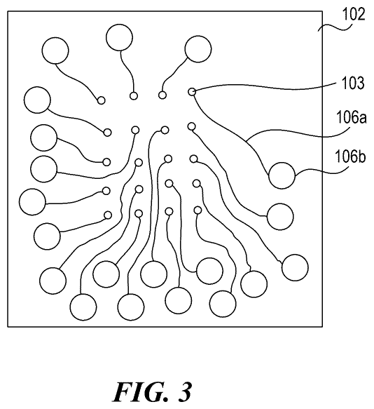

As can be seen with reference to FIG. 2, ink-jet printed conductive pads have been formed on the assembly, with a first pad 105 formed in direct contact with an exposed conductor 104 of the substrate, and a second pad (including both a probe pad 106b and a trace 106a) formed in direct contact with an exposed TSV 103 of the uppermost die of the stack of dies 102. Offsetting the probe pad from a delicate structure, such as a TSV 103, may prevent damage to the TSV 103 from the mechanical deformation that can occur to a pad when probed by a metal pin. Alternatively and/or additionally, printing fine traces such as trace 106a can permit a dense array of conductors, such as an array of TSVs 103, to be “fanned-out” to an array of probe pads which would otherwise be too large to accommodate vertical alignment with the dense array of conductors. Such a benefit is illustrated more specifically in FIG. 3, in which a simplified schematic overhead view of a die 102a with a dense array of exposed TSVs 103 is illustrated with a fanned-out array of probe pads, such as probe pad 106b, by concurrently ink-jet printed traces, such as trace 106a.

The ink-jet printed pads may comprise any one of a number of conductive materials compatible with an ink-jet printing process. For example, in one embodiment, the conductive ink may comprise a plurality of conductive nanoparticles, including gold, copper, aluminum, silver, or the like. In some embodiments, the nanoparticles may comprise a metal core surrounded by a conductive polymer shell. Accordingly, the conductive pad (and traces) printed by the ink-jet method comprise a densified plurality of conductive particles, which may be sintered by a subsequent heat-treating step, or may dry into a conductive agglomeration without a heating step, following a brief delay for drying a liquid carrier medium after printing.

Following a successful testing operation utilizing the probe pads (which may leave mechanical deformation on the pads), the assembly can be encapsulated with a molding material or the like (not illustrated) to provide a hermetic seal and mechanical strength to the assembly. Subsequent steps may include forming an array of external conductors (e.g., a solder ball grid array) on the assembly, the addition of a lid or heat sink, and/or an RFI shield, as will be readily understood by those of skill in the art.

Although in the foregoing example embodiments of semiconductor device assemblies have been illustrated and described as including post-stacking ink-jet printed probe pads, in other embodiments other conductive structures may be provided post-stacking via ink-jet printing, besides probe pads and traces connecting thereto, mutatis mutandis (e.g., solder ball pads, inductors for wireless contact, etc.).

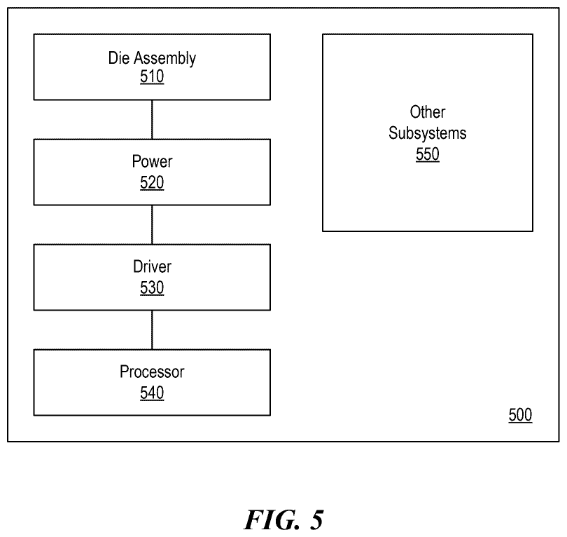

FIG. 5 is a flow chart illustrating a method of making a semiconductor device assembly. The method includes vertically stacking at least one semiconductor device over a substrate (box 510). The method further includes ink-jet printing, after vertically stacking the at least one semiconductor device, a conductive pad on an exposed conductor of the at least one semiconductor device or of the substrate (box 520). The method can further include testing an electrical circuit of the semiconductor device assembly by electrically probing the electrical circuit through the conductive pad (box 530).

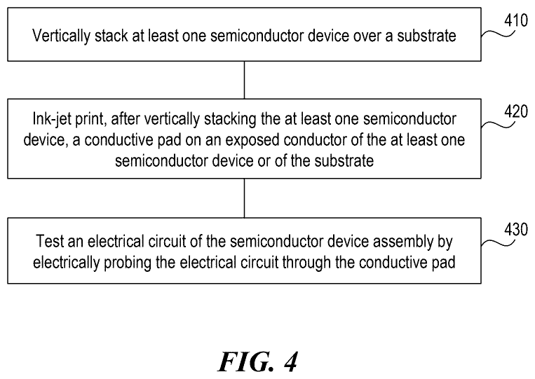

Any one of the semiconductor devices and semiconductor device assemblies described above with reference to FIGS. 1-4 can be incorporated into any of a myriad of larger and/or more complex systems, a representative example of which is system 500 shown schematically in FIG. 5. The system 500 can include a semiconductor device assembly (e.g., or a discrete semiconductor device) 502, a power source 504, a driver 506, a processor 508, and/or other subsystems or components 510. The semiconductor device assembly 502 can include features generally similar to those of the semiconductor devices described above with reference to FIGS. 2-10. The resulting system 500 can perform any of a wide variety of functions, such as memory storage, data processing, and/or other suitable functions. Accordingly, representative systems 500 can include, without limitation, hand-held devices (e.g., mobile phones, tablets, digital readers, and digital audio players), computers, vehicles, appliances and other products. Components of the system 500 may be housed in a single unit or distributed over multiple, interconnected units (e.g., through a communications network). The components of the system 500 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method for forming a semiconductor device assembly, the method comprising:
vertically stacking at least one semiconductor device over a substrate;
ink-jet printing, after vertically stacking the at least one semiconductor device, a conductive pad on an exposed conductor of the at least one semiconductor device or of the substrate.

2. The method of claim 1, wherein the exposed conductor is a trace on a portion of the substrate uncovered by the at least one semiconductor device.

3. The method of claim 1, wherein the exposed conductor is a through-silicon via (TSV) exposed on a back surface of the at least one semiconductor device.

4. The method of claim 3, wherein the conductive pad includes a conductive trace vertically aligned with the exposed conductor and a probe pad offset from the exposed conductor and electrically coupled thereto by the conductive trace.

5. The method of claim 4, wherein the conductive pad is a first conductive pad of an array of conductive pads and the TSV is a first TSV of an array of TSVs, wherein the ink-jet printing further comprises printing the array of conductive pads electrically coupled to the array of TSVs.

6. The method of claim 1, further comprising testing an electrical circuit of the semiconductor device assembly by electrically probing the electrical circuit through the conductive pad.

7. The method of claim 1, wherein ink-jet printing comprises drying the conductive pad to consolidate conductive nanoparticles thereof.

8. The method of claim 1, wherein ink-jet printing comprises heating the conductive pad to consolidate conductive nanoparticles thereof.

9. A semiconductor device assembly, comprising:
a package substrate;
one or more semiconductor devices vertically stacked over the package level substrate; and
a conductive pad formed at an upper surface of one of the one or more semiconductor devices or of the package substrate, wherein the conductive pad comprises a plurality of conductive nanoparticles.

10. The semiconductor device assembly of claim 9, wherein the package substrate comprises a second semiconductor device.

11. The semiconductor device assembly of claim 9, wherein the conductive pad is directly coupled to a conductor of the substrate or of the one or more semiconductor devices.

12. The semiconductor device assembly of claim 9, wherein the conductive pad includes a conductive trace vertically aligned and in direct contact with a TSV at an upper surface of the one or more semiconductor devices and a probe pad offset from the TSV and electrically coupled thereto by the conductive trace.

13. The semiconductor device assembly of claim 12, wherein the probe pad includes a mechanical deformation in an upper surface thereof.

14. The semiconductor device assembly of claim 12, wherein the conductive pad is a first conductive pad of a plurality of conductive pads, each including a plurality of conductive nanoparticles, and each directly coupled to a corresponding one of a plurality of TSVs at the upper surface.

15. The semiconductor device assembly of claim 9, further comprising an encapsulant at least partially surrounding the one or more semiconductor devices and the substrate.

16. The semiconductor device assembly of claim 15, wherein the encapsulant covers the conductive pad.

17. The semiconductor device assembly of claim 9, wherein the metal core of the plurality of conductive nanoparticles comprises at least one of copper, aluminum, gold, or silver.

18. The semiconductor device assembly of claim 17, wherein each conductive nanoparticle includes a metal core and a conductive polymer shell.

19. A semiconductor device assembly, comprising:
a plurality of vertically stacked semiconductor devices;
a plurality of TSVs exposed at an upper surface of an uppermost one of the plurality of vertically stacked semiconductor devices; and
a plurality of conductive pads formed at the upper surface, wherein each conductive pad is in direct contact with a corresponding one of the plurality of TSVs and comprises a plurality of conductive nanoparticles.

20. The semiconductor device assembly of claim 19, wherein each conductive nanoparticle of the plurality of conductive particles of each of the plurality of conductive pads includes a metal core and a conductive polymer shell.
